(19) United States
(12) Patent Application Publication
(10) Pub. No.: US 2007/0105295 A1
(43) Pub. Date: May 10, 2007

(54) Method for forming lightly-doped-drain metal-oxide-semiconductor (LDD MOS) device

(75) Inventor: Dae Kyeun Kim, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: DongbuAnam Semiconductor Inc.

(21) Appl. No.: 11/301,819

(22) Filed: Dec. 12, 2005

Related U.S. Application Data
(60) Provisional application No. 60/735,022, filed on Nov. 8, 2005.

(51) Int. Cl. H01L 21/336; H01L 21/8234

(52) U.S. Cl. 438/197

(57) ABSTRACT

An improved process for forming LDD MOS devices is disclosed herein. According the embodiments of the present invention, the LDD MOS structure can include a gate oxide and a gate electrode formed in a recessed region of a semiconductor substrate. The recessed region may be formed by selectively removing a nitride layer on the substrate to form an opened area for the gate, and then etching the exposed substrate surface by the opened area until a predetermined depth is reached. The depth of the recessed region may be controlled in consideration of the profile of lightly doped drain regions. Among the advantages of embodiments of the present invention are substantial prevention of the GIDL and reduction of parasitic capacitance as compared to conventional LDD MOS devices.

### BACKGROUND OF THE INVENTION

1. Field of the Invention

The present invention relates generally to a process for metal oxide semiconductor (MOS) semiconductor devices, and more particularly to a method for manufacturing lightly doped drain (LDD) MOS devices.

2. Description of the Related Art

The “hot carrier effect” (also known as the “hot electron problem”) arises when device dimensions are reduced but the supply voltage is maintained constant. This causes an increase in the electric field, particularly near the drain. The intensified electric field accelerates carriers in the channel of a MOS transistor, especially energetic carriers (“hot carriers”) in the depletion layer near the drain, to be injected into the gate oxide. The hot carrier effect becomes important for smaller semiconductor devices having submicron geometry channel lengths.

The carriers injected into the gate oxide generate a voltage drop between the semiconductor substrate and the gate oxide, which results in the long-term device degradation by varying a threshold voltage of a MOS transistor or by reducing the transconductance. A number of solutions have been proposed for mitigating the problems of hot carrier injection. The most promising of these solutions is the use of a lightly doped drain (LDD) structure. This solution is discussed, for example, by Takeda, et al., “Submicrometer MOSFET Structure for Minimizing Hot-Carrier Generation”, IEEE Transactions on Electron Devices, Vol. ED-29, No. 4, April 1982, pp. 611-618. The LDD structure consists of lightly doped source/drain regions adjacent the gate electrode with heavily doped source/drain regions laterally displaced from the gate electrode. The lightly doped region, which is driven just under the gate electrode, minimizes the injection of hot carriers, and the heavily doped region provides a low resistance region for the source and drain electrodes.

FIGS. 1A to 1E are cross sectional views for illustrating a process for manufacturing a conventional semiconductor device having an LDD structure.

Referring to FIG. 1A, an isolation field oxide (not shown) may be formed by LOCOS (Local Oxidation of Silicon) or STI (Shallow Trench Isolation) on a P-type semiconductor substrate 100 to define the active and field areas. In the active area of the semiconductor substrate, a gate is generally formed in a gate formation area. Ion implantation for the control of the threshold voltage of a MOS transistor is carried out to or on the entire exposed surface of the substrate, generally before formation of the gate.

An oxide 102 for a gate insulating layer is formed on substrate 100 by thermally oxidizing the surface of the substrate. Then, on the field oxide and the gate insulating oxide 102, a gate polysilicon layer 104 is deposited by CVD (Chemical Vapor Deposition). The gate polysilicon layer 104 has electrical conductivity by using doped polysilicon or performing ion implantation into a deposited undoped polysilicon material.

Photoresist is deposited on the polysilicon layer 104 and exposure and development processes are performed using a photo mask that defines a gate electrode to form a photoresist pattern (not shown) that covers the gate area. Portions of the gate polysilicon and gate insulating oxide that are not covered by the photoresist pattern are removed by anisotropic etching (e.g., dry etching) to form a gate pattern 104 having a topology protruding from the substrate surface.

Next, referring to FIG. 1B, N-type ion implantation of a dopant at a low concentration is performed in the exposed active area of the substrate 100 using the gate pattern 104 as an implantation mask, so that lightly doped portions 106 of the source and drain regions are formed at both sides of the gate pattern.

Referring to FIG. 1C, an insulating layer 108 comprising silicon dioxide and/or silicon nitride is deposited over the gate pattern 104 and substrate 100.

Referring to FIG. 1D, sidewall spacers 108a are formed by etching the insulating layer 108 until the surface of the semiconductor substrate 100 is exposed. The sidewall spacers 108a insulate the gate 104 from the neighboring structures and are used as an ion implantation mask for forming heavily doped portions 110 (see FIG. 1E) for the source and drain regions of the MOS transistor.

Using an implantation mask comprising the gate pattern 104 and the sidewall spacers 108, ion implantation of one or more N-type dopants at a high concentration in the exposed active regions of the substrate 100 is carried out. Then, the substrate is annealed to diffuse the implanted ions and form the source and drain junctions 110 of a MOS transistor having LDD structures 106, each of which consists of the lightly doped source/drain regions 106 adjacent to the gate 104 and gate oxide 102, while the heavily doped source/drain regions 110 (see FIG. 1E) are laterally displaced from the gate 104 and gate oxide 102 by spacers 108a. Further, the conventional LDD structure has lightly doped source/drain extensions 106 extending from heavily doped source/drain regions 110, under the sidewall spacers 108 to the substrate area underlying the gate oxide (e.g., the channel region of the MOS transistor), as illustrated in FIG. 1E.

In the conventional technology, it is difficult to prevent the lightly doped source and drain regions from extending to the underlying substrate area under the gate oxide. This is because the LDD ion implantation is performed after the gate polysilicon is formed on the silicon substrate. In other words, as the junction ion implantation of low concentration dopants is performed right after the formation of the gate polysilicon and subsequent thermal processing is carried out for diffusion of the implanted ions, it is inevitable that the dopants will diffuse into the substrate areas underlying the gate oxide 102.

Therefore, conventional LDD structures may have a relatively large gate-induced drain leakage (GIDL), and the resultant parasitic capacitance may degrade the electrical characteristics and performance of the semiconductor device. Accordingly, a need exists for an improved method for forming LDD MOS devices which would overcome the potential disadvantages of conventional LDD structures.

### SUMMARY OF THE INVENTION

It is, therefore, an object of present invention to provide an improved process for forming LDD MOS devices (e.g., MOS transistors having one or two LDD structures).

It is another object of the present invention to reduce or substantially prevent GIDL and parasitic capacitance in LDD MOS devices.

The foregoing and other objects and advantages of the present invention are achieved through an LDD structure in which a gate oxide and a gate electrode are in a recessed region of a semiconductor substrate. The recessed region may be formed by selectively removing an insulator (e.g., nitride) layer on the substrate to form an open area for the gate, and then etching the exposed substrate surface in the open area to a predetermined depth. The depth of the recessed region may be controlled in a manner corresponding to the profile of lightly doped drain regions.

In an embodiment of the present invention, a method for forming an LDD MOS device can include the (optionally sequential) steps of: forming a first insulating layer on or over a surface region of a semiconductor substrate, the surface region having a first conductivity type; selectively removing one or more portions of the first insulating layer to form an open area; etching, to a predetermined depth, the semiconductor substrate exposed by or in the open area to form a recessed region in the semiconductor substrate; forming a gate oxide on an exposed surface of the semiconductor substrate in the recessed region; forming a gate electrode on the gate oxide; performing a first ion implantation of a second conductivity type to form lightly doped regions using the gate electrode as a first mask; depositing a second insulating material on the gate electrode and the first insulating layer; anisotropically etching the second insulating material to form sidewall spacers on sides of the gate electrode; performing a second ion implantation of the second conductivity type to form heavily doped regions using the gate electrode and the sidewall spacers as a second mask; and performing a thermal process to form source and drain regions.

### BRIEF DESCRIPTION OF DRAWINGS

FIGS. 1A to 1E are cross-sectional views for illustrating a conventional method for forming a MOS transistor having an LDD structure.

FIGS. 2A to 2F are cross-sectional views for illustrating an improved method for manufacturing a MOS transistor having an LDD structure according to embodiments of the present invention.

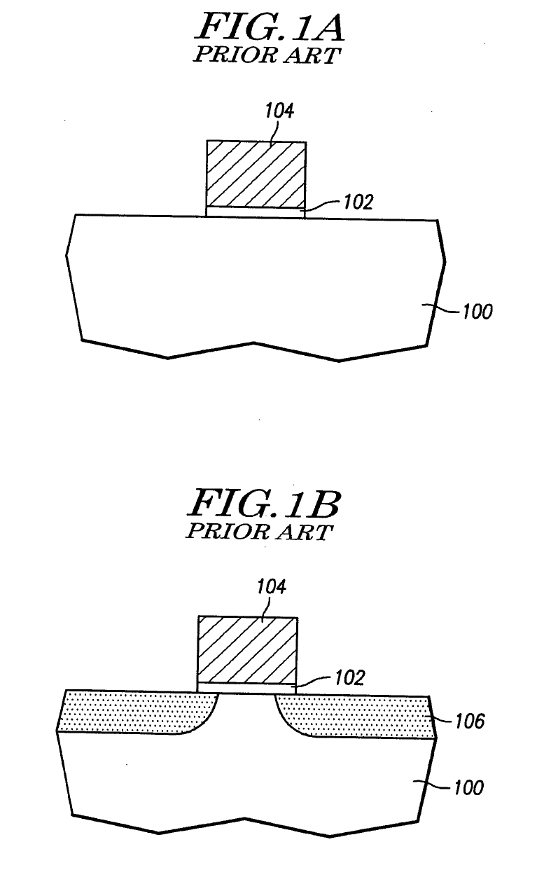

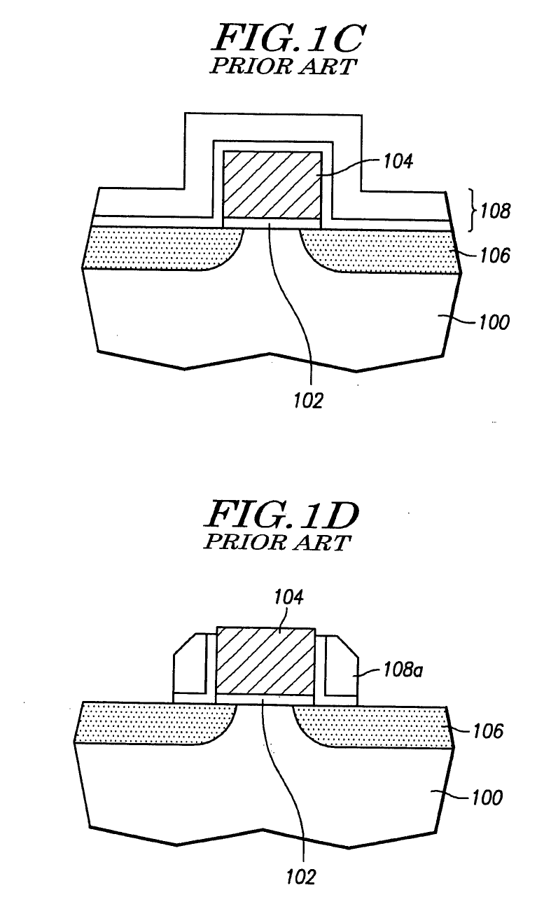

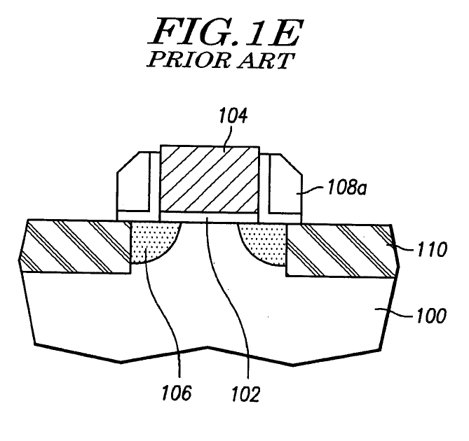

### DETAILED DESCRIPTION OF THE INVENTION

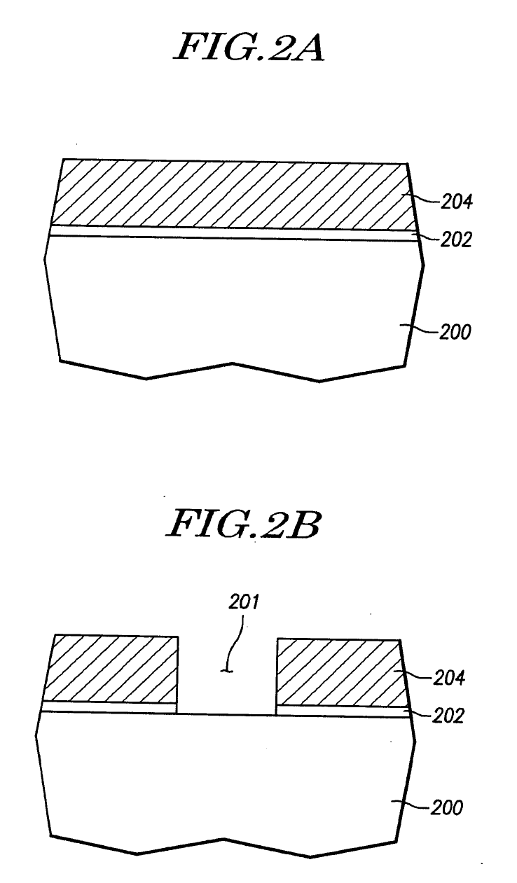

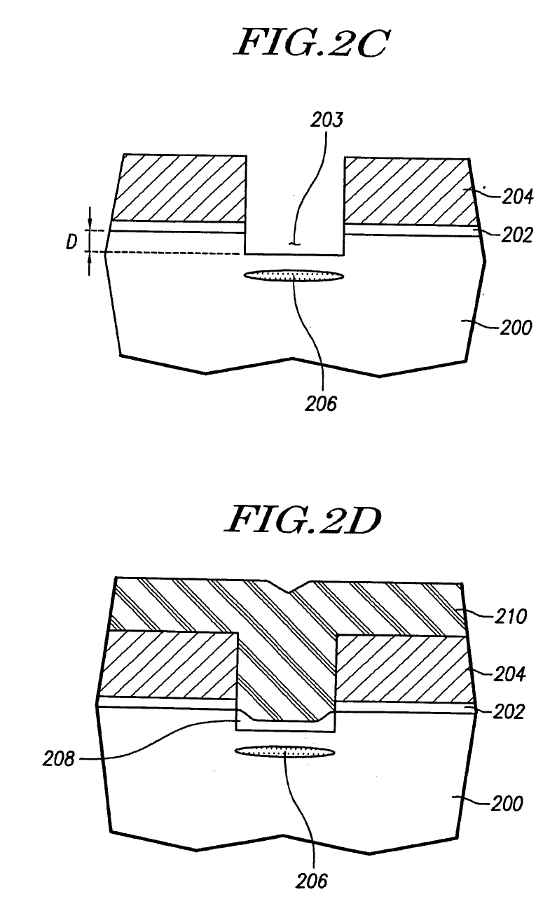

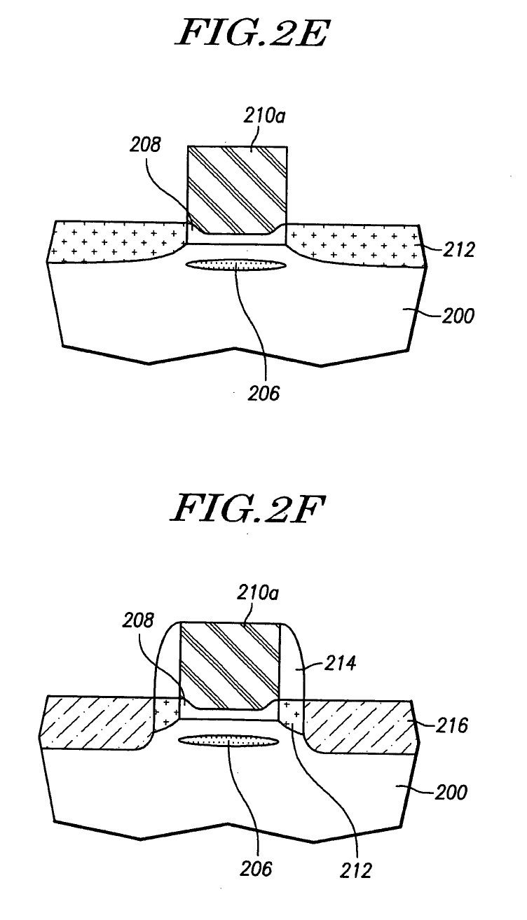

FIG. 2A shows, in cross-section, a semiconductor substrate 200 having a pad oxide layer 202 and a silicon nitride layer 204 formed thereon. The substrate of FIG. 2A may comprise, for example, N-type silicon, and thus FIGS. 2A to 2E may illustrate the fabrication of an exemplary P-channel MOS transistor. However, it should be noted that the present invention is applicable to N-channel MOS transistors and to the simultaneous fabrication of a number of MOS transistors in CMOS integrated circuits, for example.

The silicon substrate 200 has active and field regions that are defined by an isolation layer and/or isolation structures (not shown). The isolation layers may be formed by conventional LOCOS and/or STI, and may thus comprise conventional field oxide and/or shallow trench isolation structures. Further, though not shown in FIG. 2A, in the active region of the substrate 200 is formed a trench where MOS transistors are to be formed (see, e.g., FIG. 2C). For controlling a threshold voltage of MOS transistors, one or more ion implantations may be performed on the entire surface of the substrate 200, either through the pad oxide 202 (e.g., before depositing the nitride layer 204) or into the exposed substrate 200 (e.g., before depositing the pad oxide layer 202).

Referring to FIG. 2B, photoresist (not shown) is deposited on a pad oxide layer 202 and nitride layer 204, and portions of the oxide and nitride layers (e.g., 202 and 204) generally corresponding to the gate electrode region are selectively removed through a photolithographic process to form an open area 201 for the gate electrode.

When the oxide and nitride layers 202 and 204 are etched, the surface of semiconductor substrate 200 exposed by or in the open area 201 may be etched to a predetermined depth (e.g., “D”) to form a recessed region 203 in substrate 200, as shown in FIG. 2C. In an embodiment of the present invention, the nitride layer 204 comprises a silicon nitride layer, and etching may be conducted under or at one or more (e.g., all) of the following conditions: a power of from about 200 to about 1,000 W, using an etchant gas that comprises or consists essentially of an oxygen source (e.g., O₂, O₃, etc.) and a hydrofluorocarbon (e.g., CₓH_{y}F_{z}, where x is an integer of from 1 to 5, y is an integer of at least 1, and [y+z]=[2x+2] or, when x≧3, [y+z]=2x, such as CHF₃, CH₂F₂, C₂HF₅, C₂H₂F₄, cyclo-C₃H₂F₄, etc.) in a ratio of from about 2:1 to about 1:5 (e.g., about 1:2), and a fluorocarbon flow rate of from about 5 to about 200 sccm (e.g., a CHF₃ flow that ranges from about 20 to about 80 sccm). For etching substrate 200, the conditions may include one or more of the following: an etchant comprising or consisting essentially of one or more halide sources (e.g., HBr, HCl, Cl₂, Br₂, etc.) and an oxygen source (as described above) in a ratio of from about 10:1 to about 100:1 (e.g., HBr:O₂:Cl₂ in a ratio of about 30:1:4), and/or a flow rate of one halide source (e.g., HBr) is preferably from about 50 to about 250 sccm. The end point of nitride etching may be controlled by a commercial end point detection (EPD) system, while the etching depth of the substrate (i.e., the depth “D” of the recessed region 203) may be controlled by the etching time, for example.

In the present invention, the etching depth “D” of the semiconductor substrate 200 should be controlled with respect to or in a manner corresponding to the profile of lightly doped region (e.g., 212 in FIG. 2F). In an embodiment of the present invention, the etching depth “D” of the substrate 200 is determined such that the bottom of a gate oxide lies lower than the depth of a lightly doped region that is formed after the thermal process for the diffusion of implanted ions. In other words, the etching depth “D” of the substrate 200 is greater than the implant depth of lightly doped region 212.

The purposes of forming the recessed (e.g., concaved) region in the substrate 200 include: inhibition, prevention, or reducing the likelihood of a lightly doped source/drain region from extending into the substrate region underlying the gate oxide (e.g., the channel region); minimizing any overlapping regions of the gate oxide and the lightly doped source/drain regions; prevention of damage to the gate oxide resulting from etching the nitride layer; and reduction or prevention of damage to a MOS device from channel ion implantation.

After the formation of the recessed region 203 in the substrate 200, for adjusting electrical characteristics of MOS transistors, a channel implantation may be performed through the window or opening provided by the recessed region 203 to form a channel implant region 206, as shown in FIG. 2C. As the channel implant region 206 may be formed through this window while the substrate 200 is covered with and protected by the nitride layer 204 (that is subsequently removed), little or no implantation damages are caused to the MOS devices.

Next, referring to FIG. 2D, a gate oxide 208 may be deposited or grown on the exposed surface of substrate 200 (e.g., the surface exposed through the recessed region 203 of FIG. 2C). The gate oxide 208 preferably comprises silicon dioxide, and thus an oxide layer 208 is generally formed on the exposed silicon surface of substrate 200 in the recess 203. Silicon dioxide may be grown on the exposed silicon surface of substrate 200 in the recess 203 by conventional wet or dry thermal oxidation of silicon. Then, polysilicon 210 is deposited over the nitride layer 204 and on the gate oxide 208 to fill the window and recess 203. The polysilicon 210 may be deposited by a conventional CVD method, and either doped polysilicon or undoped polysilicon material may be used. When an undoped polysilicon is employed, subsequent ion implantation can provide the polysilicon 210 with suitable and/or predetermined electrical properties (e.g., conductivity).

Referring to FIG. 2E, the polysilicon layer 210 may be planarized by, e.g., a chemical mechanical polishing (CMP) process and/or a conventional etch back process (e.g., anisotropically etched using the nitride layer 204 as an etch stop layer) to form a gate electrode 210a. Then, the nitride layer 204 and the pad oxide layer 202 are removed by, e.g., a wet etching process. According to embodiments of the present invention, since the gate oxide 208 is underlying the polysilicon gate electrode 210a, the etchant for removing the nitride layer 204 cannot damage the gate oxide 208, and thus the quality of the gate oxide 208 can be sustained.

Next, using the gate electrode 210a as an ion implantation mask layer, N-type impurity ions are implanted at a low concentration into the exposed active area of the semiconductor substrate 200 to form lightly doped regions 212 at lateral sides of the gate electrode 210a. As described above, an implant depth (e.g., a concentration maximum of the dopant or a maximum depth at which an implant concentration or dose provides electrically active phenomena, such as conductivity) of lightly doped regions 212 is generally less than the depth D of the recessed portion 203 of the substrate 200, although this phenomenon may not be so clearly shown in the Figures.

Referring to FIG. 2F, a dielectric film, such as silicon dioxide or silicon nitride, is deposited on the substrate 200 to cover the entire surface of the substrate including the gate electrode 210a. This film is anisotropically etched back until the surface of the substrate 200 is exposed to form sidewall spacers 214. The sidewall spacers 214 electrically isolate the gate electrode 210a from neighboring structures, and act as a mask for ion implantation for forming the heavily doped regions 216 for the source/drain regions.

After the ion implantation for the heavily doped regions 216, a thermal process (e.g., a thermal annealing process) is performed to redistribute or diffuse the two ion implantation regions 212 and 216 to form source and drain regions. Such thermal processing (e.g., rapid thermal processing) may also repair some or substantially all damage to the crystal lattice of a silicon substrate 200 that may result from ion implantation. These source/drain regions 216 may each have a deep and heavily doped profile which is spaced away from the gate oxide 208 and gate electrode 210a, but adjacent to a more lightly doped portion 212 which is aligned with but generally does not overlap with the gate oxide 208.

As illustrated in FIG. 2F, the lightly doped regions 212 generally do not extend into the substrate area underlying the gate oxide 208 (e.g., a channel region) that is formed in the recessed area 203 of the substrate 200. Thus, problems with the conventional LDD structure such as GIDL and parasitic capacitance may be substantially overcome by the present invention. Therefore, there has been provided, in accordance with embodiments of the present invention, an improved process for forming an LDD MOS device that fully meets the objects and advantages set forth above. The present invention is advantageously applicable, in particular, to MOS field effect transistors (FETs) having submicron channel lengths, and can provide solutions for reverse short channel effects as well as short channel effects.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for forming a MOS device, said method comprising the sequential steps of:
forming a first insulating layer over or on a surface region of a semiconductor substrate, the surface region having a first conductivity type;
selectively removing a portion of the first insulating layer to form an open area;
etching, to a predetermined depth, the semiconductor substrate exposed by or in the open area to form a recessed region in the semiconductor substrate;
forming a gate oxide on an exposed surface of the recessed region;
forming a gate electrode on the gate oxide;
performing a first ion implantation of a second conductivity type to form lightly doped regions for the MOS device using the gate electrode as a first mask;
forming sidewall spacers on sides of the gate electrode;
performing a second ion implantation of the second conductivity type to form heavily doped regions for the MOS device using the gate electrode and the sidewall spacers as a second mask; and
performing a thermal process to form source and drain regions.

2. The method of claim 1, wherein the semiconductor substrate comprises silicon, and said step of etching comprises using one or more halogen sources and an oxygen source in a ratio of from about 10:1 to about 100:1.

3. The method of claim 1, wherein the semiconductor substrate comprises silicon, and said step of etching comprises using HBr:O₂:Cl₂ in a ratio of about 30:1:4 and a flow rate of HBr in a range of from about 50 sccm to about 250 sccm.

4. The method of claim 1, wherein the predetermined depth of the recessed region is controlled by an etching time.

5. The method of claim 1, wherein the first insulating layer comprises silicon nitride and the step of selectively removing a portion of the first insulating layer comprises applying a power of from about 200 W to about 1,000 W, and using an etchant gas comprising an oxygen source and a hydrofluorocarbon in a ratio of from about 5:1 to about 1:10.

6. The method of claim 5, wherein the oxygen source comprises O₂ and the hydrofluorocarbon comprises CHF₃ in a ratio of about 1:2, and a flow rate of the CHF₃ ranges from about 20 to about 80 sccm.

7. The method of claim 6, wherein an end point of etching the silicon nitride is determined by an end point detection (EPD) system.

8. The method of claim 1, wherein the predetermined depth of the recessed region is such that the bottom of the gate oxide is lower than a depth of the lightly doped region.

9. The method of claim 1, further comprising a step of performing channel ion implantation into the semiconductor substrate through the recessed region.

10. The method of claim 1, wherein the gate electrode material comprises polysilicon.

11. The method of claim 1, wherein the step of forming the gate electrode on the gate oxide further comprises the steps of:
planarizing a surface of a gate electrode material deposited onto the substrate; and
anisotropically etching the gate electrode material using the first insulating layer as an etch stop layer.

12. The method of claim 11, further comprising removing the first insulating layer by wet etching after the step of anisotropically etching the gate electrode material.

13. The method of claim 1, further comprising depositing the second insulating material on the gate electrode and the first insulating layer.

14. The method of claim 1, wherein performing the thermal process redistributes or diffuses the two lightly and heavily doped regions.

15. The method of claim 14, wherein said predetermined depth of the recessed region corresponds to a profile of the redistributed lightly doped regions.

16. AMOS device, comprising:
a recessed region in a semiconductor substrate having a first conductivity type;
a gate electrode over a gate oxide, the gate oxide being substantially within the recessed region;
lightly doped regions on sides of the recessed region, the lightly doped regions having a second conductivity type;
heavily doped regions coupled to the lightly doped regions to form source/drain regions, the heavily doped regions having the second conductivity type; and
sidewall spacers on lateral sides of the gate electrode.

17. The MOS device of claim 16, wherein at least a portion of the gate electrode is within the recessed region.

18. The MOS device of claim 16, wherein the recessed region has a depth configured such that a bottom of the gate oxide is lower than a depth of the lightly doped region.

19. The MOS device of claim 16, wherein the lightly doped regions are substantially aligned with the gate electrode and substantially located adjacent to the recessed region.

20. The MOS device of claim 16, further comprising a channel ion implantation region below the recessed region.
